(19) United States
(12) Patent Application Publication
(10) Pub. No.: US 2015/0380563 A1
(43) Pub. Date: Dec. 31, 2015

(54) DISPLAY APPARATUS AND METHOD FOR MANUFACTURING THE SAME

(71) Applicant: Samsung Display Co., Ltd., Yongin-City (KR)

(72) Inventors: Jun-Hyun Park, Suwon-Si (KR); Yoon-Ho Kim, Seoul (KR); Hyeon-Jun Lee, Hwaseong-si (KR); Kang-Moon Jo, Seoul (KR); Chong-Chul Chai, Seoul (KR)

(21) Appl. No.: 14/551,886

(22) Filed: Nov. 24, 2014

(30) Foreign Application Priority Data
Jun. 26, 2014 (KR) 10-2014-0079249
Aug. 18, 2014 (KR) 10-2014-0106712

(51) Int. Cl. H01L 29/786; H01L 27/12; G09G 3/36

(52) U.S. Cl. CPC H01L 29/78606; G09G 3/3696; H01L 27/1225; H01L 27/1222; H01L 29/78696; H01L 27/1251; H01L 27/127

(57) ABSTRACT

A display apparatus is disclosed. The display apparatus includes a display panel and a gate driving circuit. The display panel includes a base substrate and a switching transistor. The base substrate includes a display area displaying an image and a peripheral area surrounding the display area. The switching transistor includes a first gate electrode disposed on the display area, a first channel disposed on the first gate electrode, and a first source electrode and a first drain electrode being spaced apart from each other with respect to the first channel. The gate driving circuit includes a driving transistor integrated on the peripheral area of the display panel applying gate signals to the display panel. The driving transistor includes a second gate electrode disposed on the peripheral area, a second channel disposed on the second gate electrode, and a second source electrode and a second drain electrode being spaced apart from each other with respect to the second channel, wherein the second channel includes a first active layer and a second active layer disposed on the first active layer, and a thickness of the second channel is greater than a thickness of the first channel, improving reliability and lifetime of the display apparatus.

### CLAIM OF PRIORITY

This application claims priority under 35 U.S.C. §119 to Korean Patent Application No. 10-2014-0079249, filed on Jun. 26, 2014 and Korean Patent Application No. 10-2014-0106712, filed on Aug. 18, 2014, and all the benefits accruing therefrom, the content of which is herein incorporated by reference in its entirety.

### BACKGROUND OF THE INVENTION

1. Field of the Invention

Exemplary embodiments relate to a display apparatus and a method for manufacturing the display apparatus. More particularly, exemplary embodiments relate to a display apparatus with improved reliability and a method for manufacturing the display apparatus.

2. Description of the Related Art

Generally, a liquid crystal display (“LCD”) apparatus includes a first substrate including a pixel electrode, a second substrate including a common electrode and a liquid crystal layer disposed between the first and second substrates. An electric field is generated by voltages applied to the pixel electrode and the common electrode. By adjusting an intensity of the electric field, a transmittance of a light passing through the liquid crystal layer may be adjusted so that a desired image may be displayed.

Generally, a display apparatus includes a display panel and a panel driver. The display panel includes a plurality of gate lines and a plurality of data lines. The panel driver includes a gate driver providing gate signals to the gate lines and a data driver providing data voltages to the data lines.

The gate driver includes a plurality of switching elements. Each of the switching elements may be a thin film transistor (“TFT”). When a relatively high voltage is applied between a drain electrode and a source electrode of the switching element in the gate driving circuit, a characteristic of the switching element is changed so that a reliability of the gate driving circuit may be deteriorated and a lifetime of the gate driving circuit may be shortened.

### SUMMARY OF THE INVENTION

Exemplary embodiments provide a display panel comprising a gate driving circuit with improved reliability.

Exemplary embodiments also provide a method for manufacturing the display apparatus.

In accordance with an exemplary embodiment, a display apparatus includes a display panel and a gate driving circuit. The display panel includes a base substrate and a switching transistor. The base substrate includes a display area displaying an image and a peripheral area surrounding the display area. The switching transistor includes a first gate electrode disposed on the display area, a first channel disposed on the first gate electrode, and a first source electrode and a first drain electrode being spaced apart from each other with respect to the first channel. The gate driving circuit includes a driving transistor integrated on the peripheral area of the display panel applying gate signals to the display panel. The driving transistor includes a second gate electrode disposed on the peripheral area, a second channel disposed on the second gate electrode, and a second source electrode and a second drain electrode being spaced apart from each other with respect to the second channel, wherein the second channel includes a first active layer and a second active layer being disposed on the first active layer, and a thickness of the second channel is greater than a thickness of the first channel.

In an embodiment, the second active layer and the first channel may be formed of a same layer.

In an embodiment, an etch stopper may be disposed between the first active layer and the second active layer.

In an embodiment, the second active layer of the driving transistor may be partially removed to expose the etch stopper.

In an embodiment, the etch stopper may include silicon oxide (SiOₓ) or silicon nitride (SiNₓ).

In an embodiment, the first or second channel may include amorphous silicon semiconductor or oxide semiconductor.

In an embodiment, the first or second channel may include an oxide of indium (In), zinc (Zn), gallium (Ga) or tin (Sn).

In an embodiment, a protection layer may cover the switching transistor and the driving transistor.

In an embodiment, the protecting layer may have a contact hole exposing the first drain electrode.

In an embodiment, a pixel electrode may be electrically connected to the first drain electrode through the contact hole.

In accordance with an exemplary embodiment, a method for manufacturing a display apparatus is provided. According to the method, a first gate electrode and a second gate electrode are formed on a base substrate. The base substrate includes a display area displaying an image and a peripheral area surrounding the display area. A gate insulating layer is formed covering the first and second gate electrodes. The first gate electrode is disposed on the display area and the second gate electrode is disposed on the peripheral area. The first active layer is formed and overlaps the second gate electrode. A first channel and a second channel are formed. The first channel overlaps the first gate electrode, and the second channel includes the first active layer and a second active layer. The second active layer overlaps the first active layer. A thickness of the second channel is greater than a thickness of the first channel. A first source electrode, a first drain electrode, a second source electrode, and a second drain electrode are formed. The first source electrode and the first drain electrode are spaced apart from each other with respect to the first channel. The second source electrode and the second drain electrode are spaced apart from each other with respect to the second channel.

In an embodiment, the second active layer and the first channel are formed of a same layer.

In an embodiment, a first coating layer may be coated on the gate insulating layer. A first active layer may be formed by using a first mask. The first mask may include a transparent area and a non-transparent area overlapping the second gate electrode.

In an embodiment, an etch stopper may be formed on the first coating layer overlapping the second gate electrode.

In an embodiment, an inorganic insulating layer may be formed on the first coating layer. A photoresist may be coated on the inorganic insulating layer. The inorganic insulating layer and the photoresist may be etched by using the first mask to form a photoresist pattern and the etch stopper. The first coating layer may be etched to form the first active layer. The photoresist pattern may be removed.

In an embodiment, the inorganic insulating layer may include silicon oxide (SiOₓ) or silicon nitride (SiNₓ)

In an embodiment, the first and second channels may include amorphous silicon semiconductor or oxide semiconductor.

In an embodiment, the first and second channels may include an oxide of indium (In), zinc (Zn), gallium (Ga) or tin (Sn).

According to the display panel and the method for manufacturing the display apparatus, a thickness of a channel of a transistor included in the gate driving circuit may be greater than a thickness of a channel of a transistor integrated on the display area. Therefore, a reliability and a lifetime of the gate driving circuit may be improved.

### BRIEF DESCRIPTION OF THE DRAWINGS

The above and other features and advantages of the present invention will become more apparent by describing in detail about exemplary embodiments thereof with reference to the accompanying drawings, in which:

FIG. 1 is a block diagram illustrating a display apparatus according to an exemplary embodiment;

FIG. 2 is an equivalent circuit diagram illustrating an N-th stage of the gate driver of FIG. 1;

FIG. 3 is a waveform diagram illustrating input signals, node signals and output signals of the N-th stage of the gate driver of FIG. 2;

FIG. 4 is a cross-sectional view illustrating a display panel according to an exemplary embodiment;

FIGS. 5A to 5G are cross-sectional views illustrating a method for manufacturing the display panel of FIG. 4;

FIGS. 6A to 6G are cross-sectional views illustrating a method for manufacturing the display panel of FIG. 4; and

FIG. 7 is a cross-sectional view illustrating a display panel according to an exemplary embodiment.

### DETAILED DESCRIPTION OF THE INVENTION

Hereinafter, the present invention will be explained in detail with reference to the accompanying drawings.

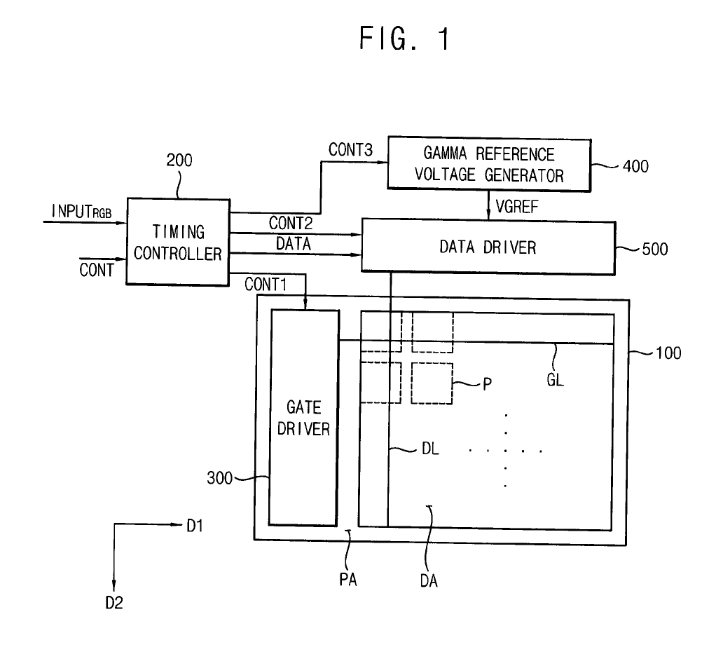

FIG. 1 is a block diagram illustrating a display apparatus according to an exemplary embodiment of the present invention.

Referring to FIG. 1, the display apparatus includes a display panel 100 and a panel driver. The panel driver includes a timing controller 200, a gate driver 300, a gamma reference voltage generator 400 and a data driver 500.

The display panel 100 has a display region on which an image is displayed and a peripheral region adjacent to the display region.

The display panel 100 includes a plurality of gate lines GL, a plurality of data lines DL and a plurality of unit pixels connected to the gate lines GL and the data lines DL. The gate lines GL extend in a first direction D1 and the data lines DL extend in a second direction D2 crossing the first direction D1.

Each unit pixel P includes a switching element (not shown), a liquid crystal capacitor (not shown) and a storage capacitor (not shown). The liquid crystal capacitor and the storage capacitor are electrically connected to the switching element. The unit pixels may be disposed in a matrix form.

The timing controller 200 receives input image data INPUT_{RGB} and an input control signal CONT from an external apparatus (not shown). The input image data may include red image data INPUT_{R}, green image data INPUT_{G} and blue image data INPUT_{B}. The input control signal CONT may include a master clock signal and a data enable signal. The input control signal CONT may include a vertical synchronizing signal and a horizontal synchronizing signal.

The timing controller 200 generates a first control signal CONT1, a second control signal CONT2, a third control signal CONT3 and a data signal DATA based on the input image data INPUT_{RGB} and the input control signal CONT.

The timing controller 200 generates the first control signal CONT1 for controlling an operation of the gate driver 300 based on the input control signal CONT, and outputs the first control signal CONT1 to the gate driver 300. The first control signal CONT1 may further include a vertical start signal and a gate clock signal.

The timing controller 200 generates the second control signal CONT2 for controlling an operation of the data driver 500 based on the input control signal CONT, and outputs the second control signal CONT2 to the data driver 500. The second control signal CONT2 may include a horizontal start signal and a load signal.

The timing controller 200 generates the data signal DATA based on the input image data INPUT_{RGB}. The timing controller 200 outputs the data signal DATA to the data driver 500.

The timing controller 200 generates the third control signal CONT3 for controlling an operation of the gamma reference voltage generator 400 based on the input control signal CONT, and outputs the third control signal CONT3 to the gamma reference voltage generator 400.

The gate driver 300 generates gate signals driving the gate lines GL in response to the first control signal CONT1 received from the timing controller 200. The gate driver 300 sequentially outputs the gate signals to the gate lines GL.

The gate driver 300 may be directly mounted on the display panel 100. For example, the gate driver 300 may be integrated on a peripheral area of the display panel 100.

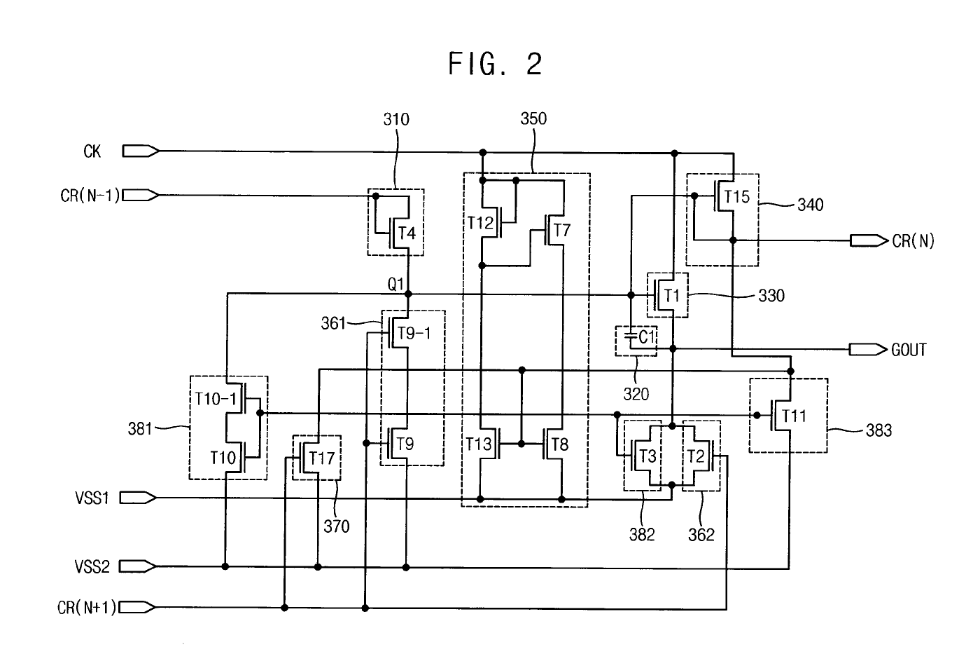

A structure of the gate driver 300 is explained referring to FIG. 2 in detail.

The gamma reference voltage generator 400 generates a gamma reference voltage VGREF in response to the third control signal CONT3 received from the timing controller 200. The gamma reference voltage generator 400 provides the gamma reference voltage VGREF to the data driver 500. The gamma reference voltage VGREF has a value corresponding to a level of the data signal DATA.

The gamma reference voltage generator 400 may be disposed in the timing controller 200, or in the data driver 500.

The data driver 500 receives the second control signal CONT2 and the data signal DATA from the timing controller 200, and receives the gamma reference voltages VGREF from the gamma reference voltage generator 400. The data driver 500 converts the data signal DATA into data voltages having an analog type using the gamma reference voltages VGREF. The data driver 500 sequentially outputs the data voltages to the data lines DL.

The data driver 500 may include a shift register (not shown), a latch (not shown), a signal processing part (not shown) and a buffer part (not shown). The shift register outputs a latch pulse to the latch. The latch temporally stores the data signal DATA. The latch outputs the data signal DATA to the signal processing part. The signal processing part generates a data voltage having an analog type based on the data signal having a digital type and the gamma reference voltage VGREF. The signal processing part outputs the data voltage to the buffer part. The buffer part compensates the data voltage to have a uniform level. The buffer part outputs the compensated data voltage to the data line DL.

The data driver 500 may be directly mounted on the display panel 100, or be connected to the display panel 100 in a tape carrier package (TCP) type. For example, the data driver 500 may be integrated on the peripheral area of the display panel 100.

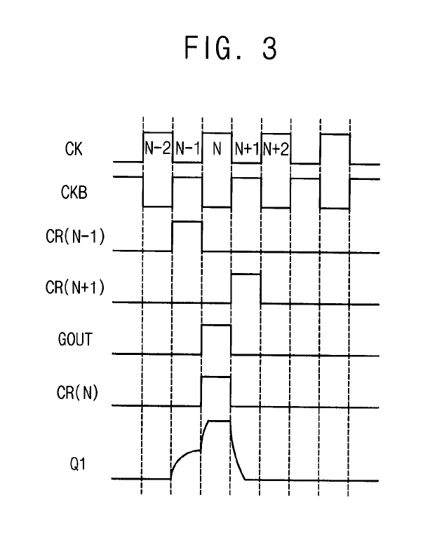

FIG. 2 is an equivalent circuit diagram illustrating an N-th stage of the gate driver 300 of FIG. 1. FIG. 3 is a waveform diagram illustrating input signals, node signals and output signals of the N-th stage of the gate driver 300 of FIG. 2.

Referring to FIGS. 1 to 3, the gate driver 300 receives a first clock signal CK, a second clock signal CKB, a first off voltage VSS1 and a second off voltage VSS2. The gate driver 300 outputs a gate output signal GOUT.

The first clock signal CK is applied to a first clock terminal The second clock signal CKB is applied to a second clock terminal. The first off voltage VSS1 is applied to a first off terminal The second off voltage VSS2 is applied to a second off terminal. The gate output signal GOUT is outputted from a gate output terminal.

The first clock signal CK is a square wave having a high level and a low level alternated with each other. The high level of the first clock signal CK may correspond to a gate on voltage. The low level of the first clock signal CK may correspond to the second gate off voltage VSS2. A duty ratio of the first clock signal CK may be 50%. Alternatively, the duty ratio of the first clock signal CK may be less than 50%. The first clock signal CK may be applied to odd-numbered stages of the gate driver 300 or to even-numbered stages of the gate driver 300. For example, the gate on voltage may be between about 15V and about 20V.

The second clock signal CKB is a square wave having a high level and a low level alternated with each other. The high level of the second clock signal CKB may correspond to the gate on voltage. The low level of the second clock signal CKB may correspond to the second gate off voltage VSS2. A duty ratio of the second clock signal CKB may be 50%. Alternatively, the duty ratio of the second clock signal CKB may be less than 50%. The second clock signal CKB may be applied to odd-numbered stages of the gate driver 300 or to even-numbered stages of the gate driver 300. For example, when the first clock signal CK is applied to the odd-numbered stages of the gate driver 300, the second clock signal CKB is applied to the even-numbered stages of the gate driver 300. For example, when the first clock signal CK is applied to the even-numbered stages of the gate driver 300, the second clock signal CKB is applied to the odd-numbered stages of the gate driver 300. For example, the second clock signal CKB may be an inverting signal of the first clock signal CK.

The first off voltage VSS1 may be a direct-current (“DC”) signal. The second off voltage may be a DC signal. The second off voltage may have a level lower than a level of the first off voltage VSS1. For example, the first off voltage VSS1 may be about −5V. For example, the second off voltage VSS2 may be about −10V.

The N-th stage outputs an N-th gate output signal GOUT and an N-th carry signal CR(N) in response to an (N−1)-th carry signal CR(N−1) of an (N−1)-th stage, which is a previous stage of the N-th stage. The N-th stage pulls down the N-th gate output signal GOUT to the first off voltage VSS1 in response to an (N+1)-th carry signal CR(N+1) of an (N+1)-th stage, which is a next stage of the N-th stage. Herein, N is a natural number.

In a similar manner, first to last stages sequentially outputs gate output signals GOUT.

The (N−1)-th carry signal CR(N−1) is applied to an (N−1)-th carry terminal The (N+1)-th carry signal CR(N+1) is applied to an (N+1)-th carry terminal. The N-th carry signal CR(N) is outputted from an N-th carry terminal.

The n-th stage includes a pull-up control part 310, a charging part 320, a pull-up part 330, a carry part 340, an inverting part 350, a first pull-down part 361, a second pull-down part 362, a carry stabilizing part 370, a first holding part 381, a second holding part 382 and a third holding part 383.

The pull-up control part 310 includes a fourth transistor T4. The fourth transistor T4 includes a control electrode and an input electrode commonly connected to the (N−1)-th carry terminal, and an output electrode connected to a first node Q1. The first node Q1 is connected to a control electrode of the pull-up part 330. Herein, the fourth transistor T4 is a pull-up control transistor.

The charging part 320 includes a charging capacitor C1. The charging capacitor C1 includes a first electrode connected to the first node Q1 and a second electrode connected to the gate output terminal.

The pull-up part 330 includes a first transistor T1. The first transistor T1 includes a control electrode connected to the first node Q1, an input electrode connected to the first clock terminal and an output electrode connected to the gate output terminal Herein, the first transistor T1 is a pull-up transistor.

The carry part 340 includes a fifteenth transistor T15 and a fourth capacitor C4. The fifteenth transistor T15 includes a control electrode connected to the first node Q1, an input electrode connected to the first clock terminal and an output electrode connected to the N-th carry terminal. Herein, the fourth transistor T15 is a carry transistor.

The inverting part 350 includes a twelfth transistor T12, a seventh transistor T7, a thirteenth transistor T13, and an eighth transistor T8. The twelfth transistor T12 includes a control electrode and an input electrode connected to the first clock terminal, and an output electrode connected to an input electrode of the thirteenth transistor T13 and a control electrode of the seventh transistor T7. The seventh transistor T7 includes a control electrode connected to the output electrode of the twelfth transistor T12, an input electrode connected to the first clock terminal and an output electrode connected to the input electrode of the eighth transistor T8. The thirteenth transistor T13 includes a control electrode connected to the N-th carry terminal, an input electrode connected to the output electrode of the twelfth transistor T12 and an output electrode connected to the first off terminal. The eighth transistor T8 includes a control electrode connected to the N-th carry terminal, an input electrode connected to the output electrode of the seventh transistor T7 and an output electrode connected to the first off terminal.

Herein, the twelfth transistor T12 is a first inverting transistor. The seventh transistor T7 is a second inverting transistor. The thirteenth transistor T13 is a third inverting transistor. The eighth transistor T8 is a fourth inverting transistor.

The first pull-down part 361 includes a plurality of switching elements connected to each other in series. For example, the first pull-down part 361 includes two transistors connected to each other in series.

For example, the first pull-down part 361 includes a ninth transistor T9 and a “9-1” transistor T9-1. The ninth transistor T9 includes a control electrode connected to the (N+1)-th carry terminal, an input electrode connected to the second off terminal and an output electrode connected to the 9-1 transistor T9-1. The 9-1 transistor T9-1 includes a control electrode connected to the (N+1)-th carry terminal, an input electrode connected to the ninth transistor T9 and an output electrode connected to the first node Q1.

Herein, the ninth transistor T9 is a first pull-down transistor. The 9-1 transistor T9-1 is a second pull-down transistor.

The second pull-down part 362 includes the second transistor T2. The second transistor T2 includes a control electrode connected to the (N+1)-th carry terminal, an input electrode connected to the first off terminal and an output electrode connected to the gate output terminal

The carry stabilizing part 370 includes a seventeenth transistor T17. The seventeenth transistor T17 includes a control electrode and an input electrode commonly connected to the (N+1)-th carry terminal, and an output electrode connected to the N-th carry terminal.

The carry stabilizing part 370 reduces a noise due to a leakage current transmitted through a fourth transistor T4 of the (N+1)-th stage.

The first holding part 381 includes a tenth transistor T10 and a “10-1” transistor T10-1. The tenth transistor T10 includes an input electrode connected to the second off terminal and an output electrode connected to the 10-1 transistor T10-1. The 10-1 transistor T10-1 includes an input electrode connected to the tenth transistor T10 and an output electrode connected to the first node Q1.

Herein, the tenth transistor T10 is a first holding transistor, the 10-1 transistor T10-1 is a second holding transistor.

The second holding part 382 includes a third transistor T3. The third transistor T3 includes an input electrode connected to the first off terminal and an output electrode connected to the gate output terminal.

The third holding part 383 includes an eleventh transistor T11. The eleventh transistor T11 includes an input electrode connected to the second off terminal and an output electrode connected to the N-th carry terminal.

In the present exemplary embodiment, although the (N−1)-th carry signal is used as a previous carry signal, the previous carry signal is not limited to the (N−1)-th carry signal. The previous carry signal may be a carry signal of one of previous stages. In addition, although the (N+1)-th carry signal is used as a next carry signal, the next carry signal is not limited to the (N+1)-th carry signal. The next carry signal may be a carry signal of one of next stages.

In the present exemplary embodiment, the first, second, third, fourth, seventh, eighth, ninth, 9-1, tenth, 10-1, eleventh, twelfth, thirteenth, fifteenth and seventeenth transistors may be oxide semiconductor transistors. Alternatively, the first, second, third, fourth, seventh, eighth, ninth, 9-1, tenth, 10-1, eleventh, twelfth, thirteenth, fifteenth and seventeenth transistors may be amorphous silicon transistors.

Referring to FIG. 3, the first clock signal CK has a high level corresponding to (N−2)-th stage, N-th stage, (N+2)-th stage and (N+4)-th stage. The second clock signal CKB has a high level corresponding to (N−1)-th stage, (N+1)-th stage and (N+3)-th stage.

The (N−1)-th carry signal CR(N−1) has a high level corresponding to the (N−1)-th stage. The (N+1)-th carry signal CR(N+1) has a high level corresponding to the (N+1)-th stage.

The gate output signal GOUT of the N-th stage is synchronized with the first clock signal CK, and has a high level corresponding to the N-th stage. The N-th carry signal CR(N) is synchronized with the first clock signal CK, and has a high level corresponding to the N-th stage.

A voltage of the first node Q1 of the N-th stage is increased to a first level corresponding to the (N−1)-th stage by the pull-up control part 310. The voltage of the first node Q1 of the N-th stage is increased to a second level, which is higher than the first level, corresponding to the N-th stage by the pull-up part 330 and the charging part 320. Thus, a high voltage stress is applied to transistors connected to the first node Q1, so that an on current holding ratio in the transistors is decreased. A carry voltage outputting to a next stage is decreased, or a carry signal is delayed so that a reliability of a panel is deteriorated. When a thickness of an active layer of the transistors connected to the first node Q1 increases, the reliability may be improved.

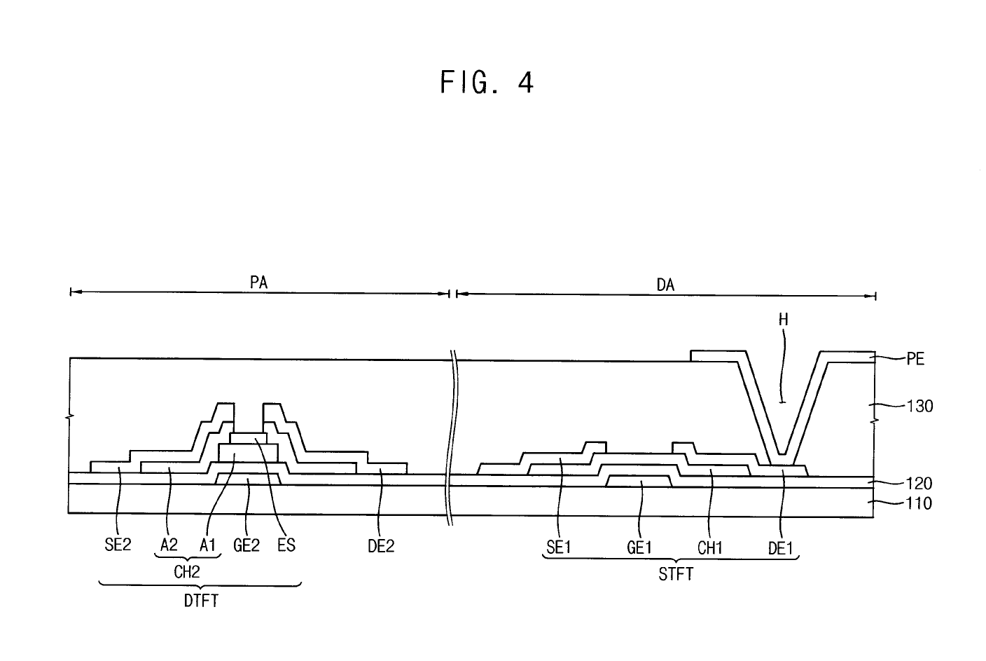

FIG. 4 is a cross-sectional view illustrating a display panel according to an exemplary embodiment.

Referring to FIGS. 1 to 4, the display apparatus includes a display panel 100, a gate driver 300 and a data driver 500. The display panel 100 includes a display area DA displaying an image and a peripheral area PA surrounding the display area DA.

The display panel 100 includes a base substrate 110. The base substrate 110 may be a transparent insulating substrate. For example, the base substrate 110 may be a glass substrate or plastic substrate.

The display area DA of the base substrate 110 may include a plurality of pixel areas for displaying an image. A plurality of the pixel areas may be disposed in a matrix shape having a plurality of rows and a plurality of columns

Each pixel area may include a switching transistor STFT for displaying an image.

The switching transistor STFT includes a first gate electrode GE1, a first channel CH1, a first source electrode SE1 and a first drain electrode DE1.

The switching transistor STFT may be connected to a corresponding gate line GL and a corresponding data line DL adjacent to the switching transistor STFT. The switching transistor STFT may be disposed at a crossing area of the gate line GL and the data line DL.

A gate pattern may include the first gate electrode GE1 and the gate line GL. The gate pattern may be disposed on the base substrate 110. The gate line GL is electrically connected to the first gate electrode GE1.

The gate insulating layer 120 may be disposed on the base substrate 110 to cover the gate pattern and may insulate the gate pattern.

The first channel CH1 may be disposed on the gate insulating layer 120. The first channel CH1 may overlap with the first gate electrode GE1.

A data pattern may include a data line DL, a first source electrode SE1 and a first drain electrode DEL The data pattern may be disposed on the gate insulating layer 120.

The first source electrode SE1 may overlap with the first channel CH1, and the first source electrode SE1 may be electrically connected with the data line DL. The first drain electrode DE1 may be spaced apart from the first source electrode SE1 with respect to the first channel CH1. The first channel CH1 may have a conductive channel between the first source electrode SE1 and the first drain electrode DE1.

For example, the first channel CH1 may include an amorphous silicon semiconductor or an oxide semiconductor.

For example, the first channel CH1 may include an oxide of indium (In), zinc (Zn), gallium (Ga) and tin (Sn). For example, the oxide may be zinc oxide (ZnOₓ), zinc gallium oxide (ZnGaₓO_{y}), zinc indium oxide (ZnInₓO_{y}), zinc tin oxide (ZnSnₓO_{y}), gallium indium zinc oxide (GaInₓZn_{y}O_{z}), tin oxide (SnOₓ), gallium tin oxde (GaSnₓO_{y}) or the like. Alternatively, for example, the first channel CH1 may include amorphous silicon, polysilicon, and the first channel CH1 may be crystallized and ion-doped.

Therefore, the switching transistor STFT may include the first gate electrode GE1, the first channel CH1, the first source electrode SE1 and the first drain electrode DE1.

A protection layer 130 is disposed on the gate insulating layer 120 to cover the data pattern and may insulate the data pattern. The protecting layer 130 has a contact hole H exposing the first drain electrode DE1.

A pixel electrode PE is disposed on the protection layer 130, and the pixel electrode PE is electrically connected to the first drain electrode DE1 of the switching transistor STFT through the contact hole H. The pixel electrode PE may be disposed on the pixel area. A gray scale voltage may be applied to the pixel electrode PE by the switching transistor STFT.

The gate driver 300 includes a gate driving circuit applying gate signals to the display panel 100. The data driver 500 includes a data driving circuit applying data signals to the display panel 100.

The gate driving circuit may be integrated in the peripheral area PA on the base substrate 110. The gate driving circuit includes a driving transistor DTFT.

The driving transistor DTFT may be continuously applied a higher voltage stress than the switching transistor STFT. Thus, the driving transistor DTFT may include a second gate electrode GE2, a second channel CH2, a second source electrode SE2 and a second drain electrode DE2. The second channel CH2 may include a first active layer Al and a second active layer A2.

More specifically, the highest voltage stress may be applied to transistors connected to the first node Q1. For example, the transistor connected to the first node Q1 is the fourth transistor T4, the first transistor T1, the fifteenth transistor T15, the 9-1 transistor T9-1 and the 10-1 transistor T10-1. The fourth transistor T4 is the pull-up control transistor. The first transistor T1 is the pull-up transistor. The fifteenth transistor T15 is the carry transistor. The 9-1 transistor T9-1 is the second pull-down transistor. The 10-1 transistor T10-1 is the second holding transistor.

The second gate electrode GE2 is disposed on the base substrate 110. The gate insulating layer 120 may be disposed on the base substrate 110 to cover the second gate electrode GE2 and may insulate the second gate electrode GE2.

The second channel CH2 may be disposed on the gate insulating layer 120. The second channel CH2 may include a first active layer Al and a second active layer A2 so that a thickness of the second channel CH2 is greater than a thickness of the first channel CH1. The second active layer A2 is disposed on the first active layer Al. For example, the second active layer A2 and the first channel CH1 may be formed of a same layer. For example, the first channel CH1 and the second channel CH2 may include a same material.

The driving transistor DTFT may include an etch stopper ES between the first active layer A1 and the second active layer A2. The second active layer A2 on the etch stopper ES may be partially removed to expose the etch stopper ES. Thus, the shortest distance of an electron migration route between the second source and drain electrodes, i.e. SE2 and DE2, may be blocked so that a distance of an electron migration route may be increased.

For example, the etch stopper ES may be disposed on the first active layer A1, and the second active layer A2 may be disposed on the etch stopper ES. Thus, the second active layer A2 may increase the distance of the electron migration route in a thickness direction of the driving transistor DTFT.

For example, the etch stopper ES may include silicon oxide (SiOₓ) or silicon nitride (SiNₓ).

The second channel CH2 may overlap the second gate electrode GE2.

The second source electrode SE2 and the second drain electrode DE2 may be disposed on the second channel CH2. The second source electrode SE2 and the second drain electrode DE2 may overlap the second channel CH2. The second source electrode SE2 and the second drain electrode DE2 may be spaced apart from each other with respect to the second channel CH2. The second channel CH2 may have a conductive channel between the second source electrode SE2 and the second drain electrode DE2.

Therefore, the driving transistor DTFT may include the second gate electrode GE2, the second channel CH2, the second source electrode SE2 and the second drain electrode DE2.

The driving transistor DTFT includes the second channel CH2 so that a thickness of an active layer of the driving transistor DTFT is greater than a thickness of an active layer of the switching transistor STFT. Thus, a distance of an electron migration route in the thickness direction of the transistor may increase so that an electric field of a transistor, which is generated by a strong applied voltage, may be reduced efficiently. However, when a thickness of an active layer of the switching transistor STFT increases, a reliability of photoelectricity may be deteriorated.

The protection layer 130 is disposed on the gate insulating layer 120 to cover the driving transistor DTFT and may insulate the second source electrode SE2 and the second drain electrode DE2.

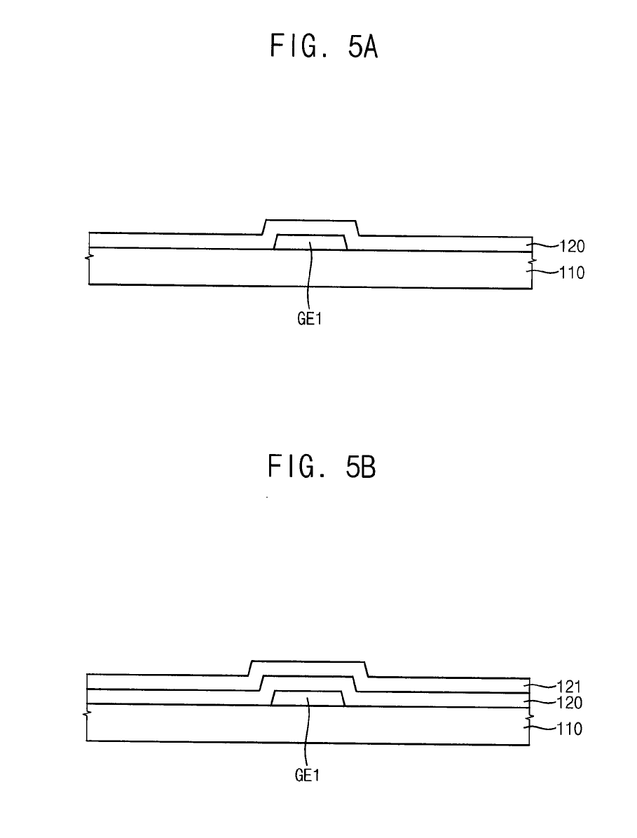

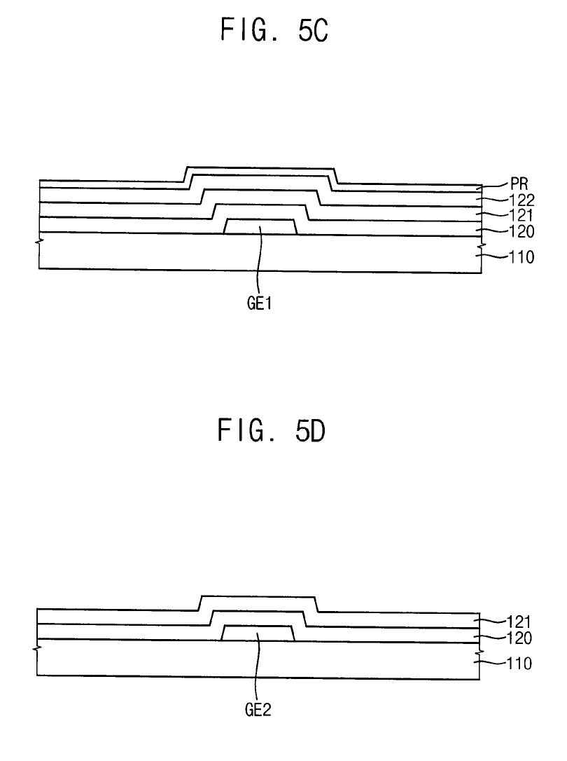

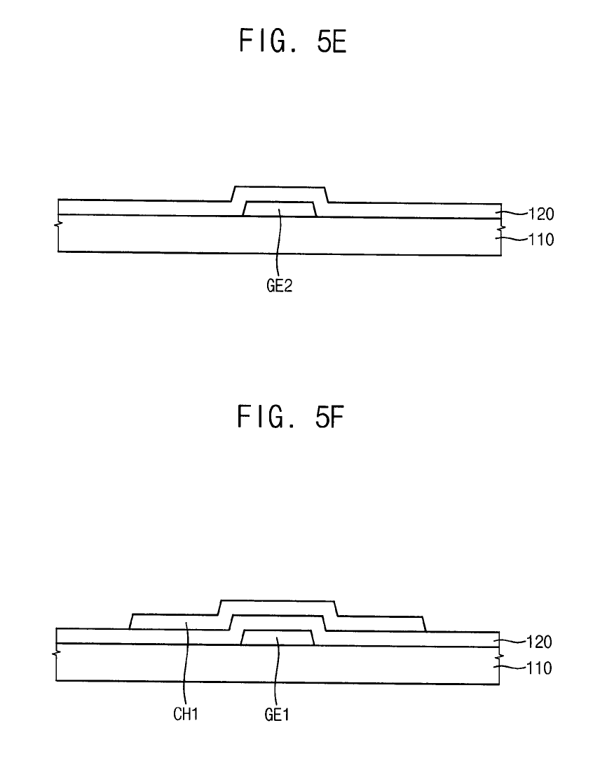

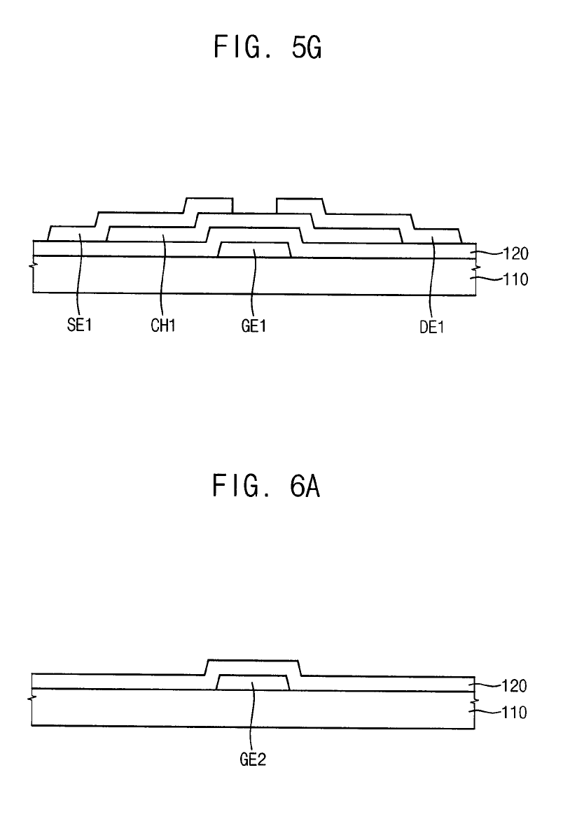

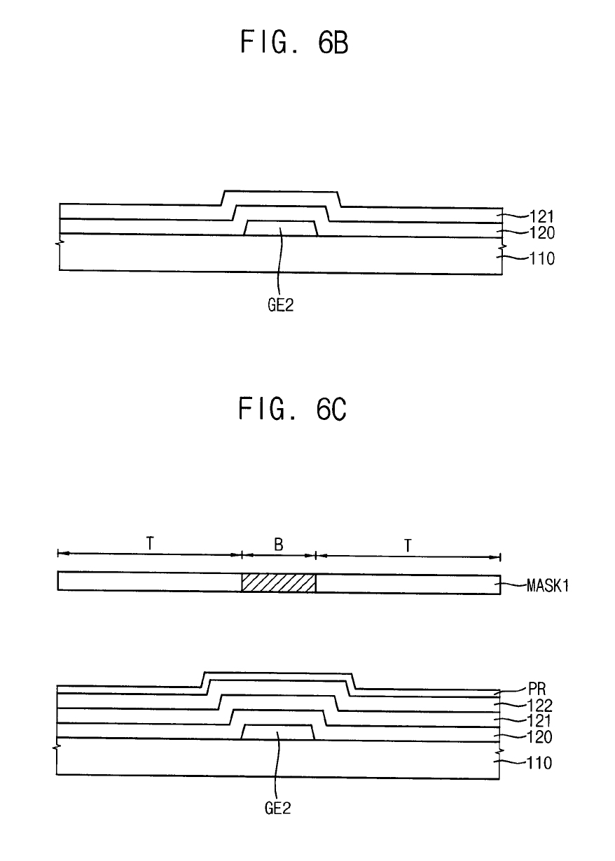

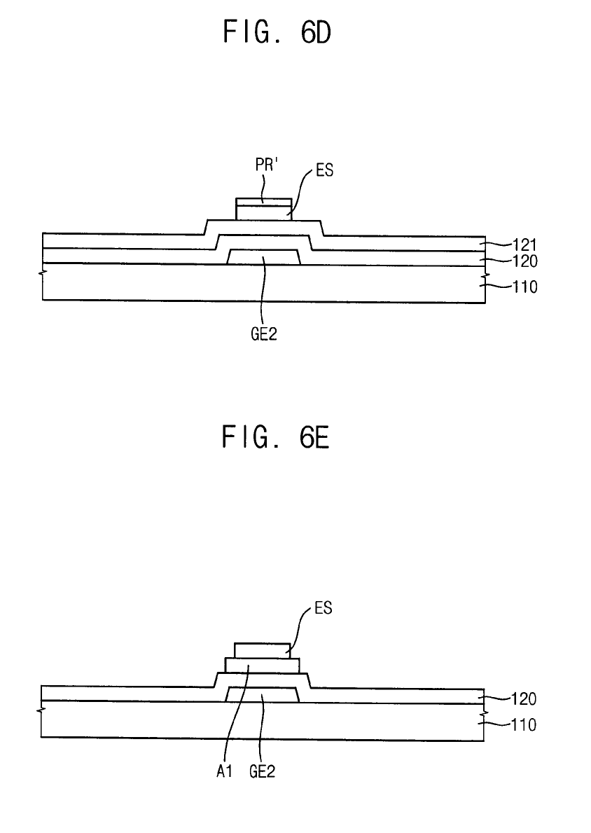

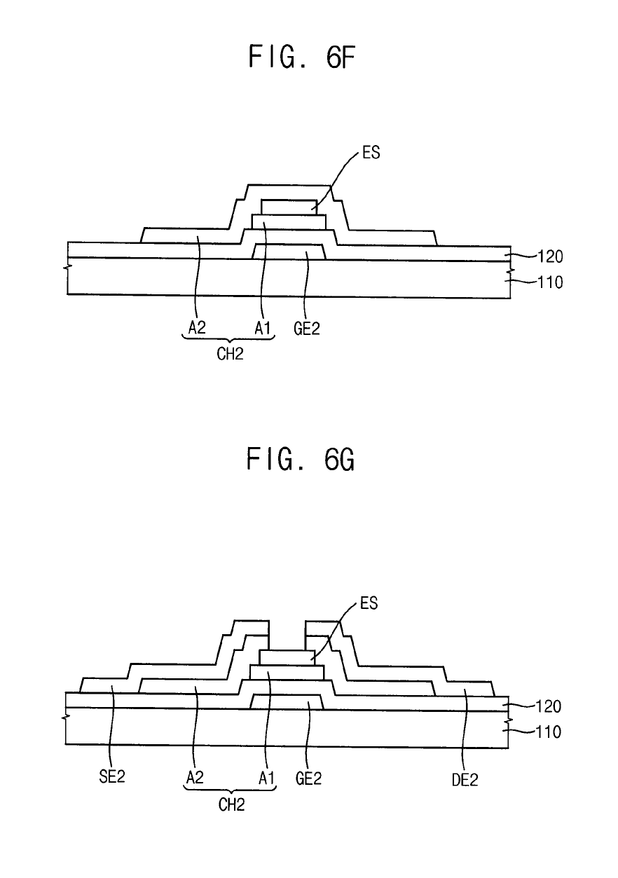

FIGS. 5A to 5G are cross-sectional views illustrating a method for manufacturing the display panel of FIG. 4. FIGS. 6A to 6G are cross-sectional views illustrating a method for manufacturing the display panel of FIG. 4.

A method for manufacturing a display apparatus according to an exemplary embodiment of the present invention will be described with reference to FIGS. 1 to 6G.

Referring to FIGS. 5A and 6A, a first gate electrode GE1 and a second gate electrode GE2 may be formed on the base substrate 110. The first gate electrode GE1 may be formed on the display area DA, and the second gate electrode GE2 may be formed on the peripheral area PA. A gate insulating layer 120 may be formed on the first gate electrode GE1 and the second gate electrode GE2. The gate insulating layer 120 may cover the first gate electrode GE1 and the second gate electrode GE2.

Referring to FIGS. 5B and 6B, a first coating layer 121 is coated on the gate insulating layer 120. For example, the first coating layer 121 may include an oxide of indium (In), zinc (Zn), gallium (Ga) or tin (Sn). Alternatively, the first coating layer 121 may include amorphous silicon, polysilicon, and the first coating layer 121 may be crystallized and ion-doped.

Referring to FIGS. 5C and 6C, an inorganic material is deposited on the first coating layer 121 to form an inorganic insulating layer 122. For example, the inorganic material may include silicon oxide (SiOₓ) or silicon nitride (SiNₓ).

A photoresist PR is coated on the inorganic insulating layer 122. The photoresist PR is coated on a whole surface of the base substrate 110.

A first mask MASK1 is disposed on the base substrate 110. For example, the first mask MASK1 may be a halftone mask including a transparent area T and a blocking area B. The blocking area B may be corresponding to the second gate electrode GE2. Thus, the photoresist except an area corresponding to the second gate electrode GE2 may be irradiated by light.

Referring to FIGS. 5D and 6D, the photoresist PR and the inorganic insulating layer 122 may be etched to form a photoresist pattern PR′ and an etch stopper ES corresponding to the second gate electrode GE2. The photoresist PR and the inorganic insulating layer 122 may be partially removed by a wet etch using an etchant or a dry etch.

Referring to FIGS. 5E and 6E, the first coating layer 121 may be partially removed by the wet etch using the etchant, to form the first active layer A1. The first active layer A1 is overlapped with the second gate electrode GE2. The first coating layer 121 except an area corresponding to the second gate electrode GE2 may be removed. Then, the photoresist pattern PR′ may be removed.

In addition, a width of the photoresist pattern PR′ may be decreased by ashing a side surface the photoresist pattern PR′, and a width of the etch stopper ES may be decreased by etch stopper by dry etching a side surface of the etch stopper ES. For example, a width of the etch stopper ES may be smaller than a width of the first active layer A1. The first active layer A1 may be partially removed under the etch stopper ES so that an under cut may occur. Thus, the width of the etch stopper ES is decreased so that the under cut may prevent.

Although it is not illustrated in the figures, alternatively, a width of the photoresist pattern PR′ and the etch stopper ES may be not decreased. Thus, a width of the etch stopper ES may be the same as a width of the first active layer A1.

Referring to FIGS. 5F and 6F, a first channel CH1 corresponding to the first gate electrode GE1 may be formed. A second active layer A2 overlapping with the first active layer A1 may be formed so that a second channel CH2 including the first and second active layers, i.e. A1 and A2, may be formed. The second channel CH2 includes the first and second active layers, i.e. A1 and A2, so that a thickness of the second channel CH2 may be greater than a thickness of the first channel CH1.

The second active layer A2 may be formed on the first active layer A1. The second active layer A2 having nonuniform thickness and contacting top and side surfaces of the first active layer A1 having uniform thickness and a smaller width than the second active layer A2 (FIG. 6F). For example, the second active layer A2 and the first channel CH1 may be formed in a same layer. For example, the first channel CH1 and the second channel CH2 may include a same material.

For example, a second coating layer may be formed on the base substrate 110. A second mask is disposed on the base substrate 110. For example, the second mask may include a blocking area overlapping with the first and second gate electrodes, i.e. GE1 and GE2. The second coating layer except an area corresponding to the first and second gate electrodes, i.e. GE1 and GE2, may be removed so that the first channel CH1 and the second active layer A2 may be patterned. Therefore, the first channel CH1 and the second channel CH2 may be formed.

Referring to FIGS. 5G and 6G, the first source or drain electrode, i.e. SE1 or DE1, is formed on the first channel CH1, and the second source or drain electrode, i.e. SE2 or DE2, is formed on the second channel CH2.

The first source, drain electrode SE1 DE1 may be overlapped with the first gate electrode GE1. The second source or drain electrode, i.e. SE2 or DE2, may be overlapped with the second gate electrode GE2.

For example, a conducting layer may be formed on the display area to form the switching transistor STFT. And then a photoresist pattern may be formed on the conducting layer corresponding to the first source or drain electrode, i.e. SE1 or DE1. The photoresist pattern may be overlapped with the first gate electrode GE1. The conducting layer may be irradiated and etched. Thus, the first source or drain electrode, SE1 or DE1, may be formed on the first channel CH1.

For example, a conducting layer may be formed on the peripheral area to form the driving transistor DTFT, and the conducting layer may cover the etch stopper ES. And then a photoresist pattern may be formed on the conducting layer corresponding to the second source or drain electrode, SE2 or DE2. The photoresist pattern may be overlapped with the second gate electrode GE2. The conducting layer may be irradiated and the conducting layer and the second active layer A2 may be etched at the same time. Thus, the second source or drain electrode, SE2 or DE2, may be formed on the second channel CH2.

The second active layer A2 deposited on the etch stopper ES may be partially removed to expose the etch stopper ES. Thus, the shortest distance of an electron migration route between the second source electrode SE2 and the second drain electrode DE2 may be blocked so that a distance of an electron migration route may be increased.

The driving transistor DTFT, which is disposed on the peripheral area PA, may include the second channel CH2, so that a thickness of an active layer may be increased.

Therefore, a distance between the second gate electrode GE2 and the second source or drain electrode, i.e. SE2 or DE2, may be increased. Therefore, although a strong voltage is applied to the first node Q1, a vertical electric field of the driving transistor DTFT may be reduced efficiently so that a reliability may be improved. A thickness of the active layer may be increased so that an effective channel length may be increased. Thus, a lateral electric field may be reduced so that a reliability may be improved. In addition, when the thickness of the active layer increases, a distance of an electron migration route in the thickness direction of the transistor may be increased so that a leakage current may be decreased. The switching transistor STFT may include the first channel CH1, so that the thickness of the channel of the switching transistor STFT may be smaller than the thickness of the channel of the driving transistor DTFT.

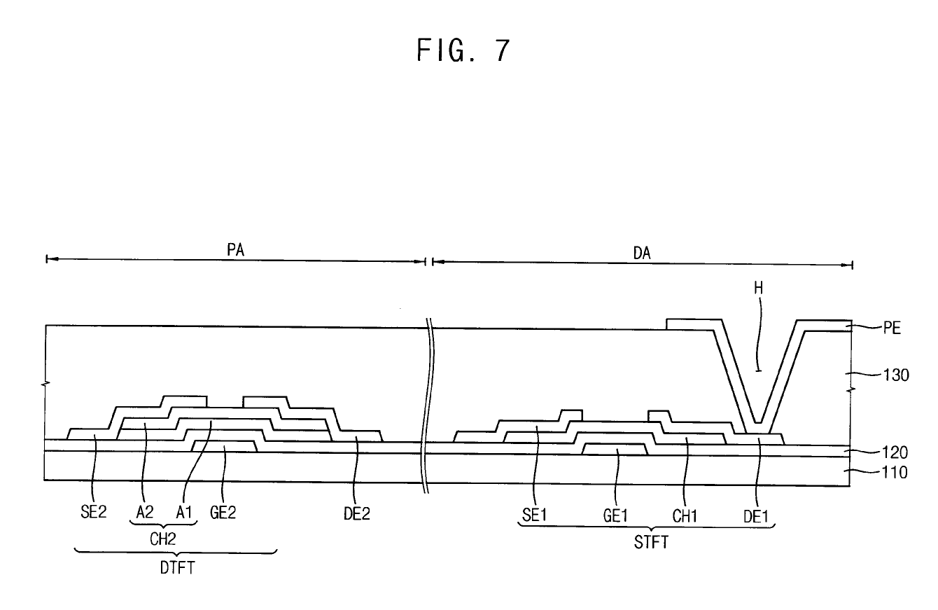

FIG. 7 is a cross-sectional view illustrating a display panel according to an exemplary embodiment.

Referring to FIGS. 1, 2, 3 and 7, the display apparatus includes a display panel 100, a gate driver 300 and a data driver 500. The display apparatus of FIG. 7 may be substantially the same as the previously explained display apparatus of FIG. 4 except a driving transistor DTFT. Thus, any duplicative explanation will be omitted.

The gate driving circuit may be integrated in the peripheral area PA on the base substrate 110. The gate driving circuit includes a driving transistor DTFT.

The driving transistor DTFT may be continuously applied a higher voltage stress than the switching transistor STFT. Thus, the driving transistor DTFT may include a second gate electrode GE2, a second channel CH2, a second source electrode SE2 and a second drain electrode DE2. The second channel CH2 may include a first active layer A1 and a second active layer A2.

The gate electrode GE2 may be disposed on the base substrate 110. The gate insulating layer 120 may be disposed on the base substrate 110 to cover the second gate electrode GE2 and may insulate the second gate electrode GE2.

The second channel CH2 may be disposed on the gate insulating layer 120. The second channel CH2 may include a first active layer A1 and a second active layer A2 so that a thickness of the second channel CH2 is greater than a thickness of the first channel CH1. The second active layer A2 is disposed on the first active layer A1. The second active layer A2 may have a same cross-sectional shape as the first active layer A1 so that a thickness of the second channel is greater than a thickness of the first channel (FIG. 7). For example, the second active layer A2 and the first channel CH1 may be formed of a same layer. For example, the first channel CH1 and the second channel CH2 may include a same material.

According to exemplary embodiments of the present invention, a display apparatus and a method for manufacturing the display apparatus may be used for a liquid crystal display apparatus, an organic light emitting apparatus or the like.

The foregoing is illustrative of the present invention and is not to be construed as limiting thereof. Although a few exemplary embodiments of the present invention have been described, those skilled in the art will readily appreciate that many modifications are possible in the exemplary embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific exemplary embodiments disclosed, and that modifications to the disclosed exemplary embodiments, as well as other exemplary embodiments, are intended to be included within the scope of the appended claims. The present invention is defined by the following claims, with equivalents of the claims to be included therein.

What is claimed is:

1. A display apparatus comprising:
a display panel comprising:
a base substrate comprising a display area displaying an image and a peripheral area surrounding the display area, and
a switching transistor comprising a first gate electrode disposed on the display area, a first channel disposed on the first gate electrode, and a first source electrode and a first drain electrode being spaced apart from each other with respect to the first channel; and
a gate driving circuit comprising:
a driving transistor integrated on the peripheral area of the display panel applying gate signals to the display panel, and the driving transistor comprising a second gate electrode disposed on the peripheral area, a second channel disposed on the second gate electrode, and a second source electrode and a second drain electrode being spaced apart from each other with respect to the second channel,
the second channel comprises a first active layer and a second active layer disposed on the first active layer, and a thickness of the second channel is greater than a thickness of the first channel.

2. The display apparatus of claim 1, wherein the second active layer and the first channel is formed of a same layer.

3. The display apparatus of claim 1, further comprising an etch stopper disposed between the first active layer and the second active layer.

4. The display apparatus of claim 3, wherein the second active layer of the driving transistor is partially removed to expose the etch stopper.

5. The display apparatus of claim 3, wherein the etch stopper comprises silicon oxide (SiOₓ) or silicon nitride (SiNₓ).

6. The display apparatus of claim 1, wherein the first or second channel comprises amorphous silicon semiconductor or oxide semiconductor.

7. The display apparatus of claim 6, wherein the first or second channel comprises an oxide of at least one selected from the group comprising indium (In), zinc (Zn), gallium (Ga) and tin (Sn).

8. The display apparatus of claim 1, further comprising a protection layer covering the switching transistor and the driving transistor.

9. The display apparatus of claim 8, the protecting layer having a contact hole exposing the first drain electrode.

10. The display apparatus of claim 9, further comprising a pixel electrode electrically connected to the first drain electrode through the contact hole.

11. A method for manufacturing a display apparatus comprising:
forming a first gate electrode, a second gate electrode on a base substrate comprising a display area displaying an image and a peripheral area surrounding the display area and a gate insulating layer covering the first and second gate electrodes, and the first gate electrode disposed on the display area and the second gate electrode disposed on the peripheral area;
forming the first active layer overlapping with the second gate electrode;
forming a first channel and a second channel, the first channel overlapping with the first gate electrode, and the second channel comprising the first active layer and a second active layer overlapping with the first active layer, and a thickness of the second channel greater than a thickness of the first channel; and
forming a first source electrode, a first drain electrode, a second source electrode, and a second drain electrode, the first source electrode and the first drain electrode being spaced apart from each other with respect to the first channel and the second source electrode and the second drain electrode being spaced apart from each other with respect to the second channel.

12. The method of claim 11, wherein the second active layer and the first channel is formed of a same layer.

13. The method of claim 11, the step of forming the first active layer comprises:
coating a first coating layer on the gate insulating layer; and
forming a first active layer by using a first mask comprising a transparent area and a non-transparent area overlapping with the second gate electrode.

14. The method of claim 13, further comprising forming an etch stopper on the first coating layer to overlap the second gate electrode.

15. The method of claim 14, wherein the step of forming the etch stopper comprises:
forming an inorganic insulating layer on the first coating layer;
coating a photoresist on the inorganic insulating layer;
etching the inorganic insulating layer and the photoresist by using the first mask to form a photoresist pattern and the etch stopper;
etching the first coating layer to form the first active layer; and
removing the photoresist pattern.

16. The method of claim 15, wherein the inorganic insulating layer comprises silicon oxide (SiOₓ) and silicon nitride (SiNₓ).

17. The method of claim 11, the first and second channels comprising amorphous silicon semiconductor and oxide semiconductor.

18. The method of claim 17, the first and second channels comprising an oxide of at least one selected from the group comprising indium (In), zinc (Zn), gallium (Ga) and tin (Sn).

19. A display apparatus of claim 1, the second active layer having nonuniform thickness and contacting top and side surfaces of the first active layer having uniform thickness and a smaller width than the second active layer.

20. A display apparatus comprising:
a display panel comprising:
a base substrate comprising a display area displaying an image and a peripheral area surrounding the display area, and
a switching transistor comprising a first gate electrode disposed on the display area, a first channel disposed on the first gate electrode, and a first source electrode and a first drain electrode being spaced apart from each other with respect to the first channel; and
a gate driving circuit comprising:
a driving transistor integrated on the peripheral area of the display panel applying gate signals to the display panel, and the driving transistor comprising a second gate electrode disposed on the peripheral area, a second channel disposed on the second gate electrode, and a second source electrode and a second drain electrode being spaced apart from each other with respect to the second channel,
the second channel comprises a first active layer and a second active layer disposed on the first active layer, the first active layer having a same cross-sectional shape as the second active layer so that a thickness of the second channel is greater than a thickness of the first channel.
